(19) United States
(12) Patent Application Publication
(10) Pub. No.: US 2026/0029591 A1
(43) Pub. Date: Jan. 29, 2026

(54) Semiconductor Device and Method of Making a Double-Sided Co-Packaged Optics Module

(71) Applicant: STATS ChipPAC Pte. Ltd., Singapore (SG)

(72) Inventors: Swain Hong Alfred Yeo, Singapore (SG); Kai Chong Chan, Singapore (SG); Linda Pei Ee Chua, Singapore (SG)

(73) Assignee: STATS ChipPAC Pte. Ltd., Singapore (SG)

(21) Appl. No.: 18/784,404

(22) Filed: Jul. 25, 2024

(51) Int. Cl. H01L 23/00; G02B 6/42; H01L 23/31; H01L 23/49; H01L 25/16

(52) U.S. Cl. CPC H01L 24/25; G02B 6/424; G02B 6/4255; H01L 23/3107; H01L 23/49; H01L 24/20; H01L 24/24; H01L 24/82; H01L 25/167; H01L 24/16; H01L 24/32; H01L 24/73; H01L 24/96; H01L 2224/16227; H01L 2224/211; H01L 2224/24146; H01L 2224/24226; H01L 2224/2518; H01L 2224/32225; H01L 2224/73204; H01L 2224/82005; H01L 2224/95001

(57) ABSTRACT

A semiconductor device has a photonic semiconductor die. The photonic semiconductor die is disposed on a carrier with a photonic circuit of the photonic semiconductor die oriented toward the carrier. An e-bar is disposed on the carrier. An encapsulant is deposited over the photonic semiconductor die and e-bar. A first surface of the encapsulant is backgrinded to expose the e-bar. A first build-up interconnect structure is formed over the first surface of the encapsulant. A second build-up interconnect structure is formed over a second surface of the encapsulant. The photonic circuit is exposed through an opening of the second build-up interconnect structure.

### FIELD OF THE INVENTION

The present invention relates in general to semiconductor devices and, more particularly, to a semiconductor device and method of making a double-sided co-packaged optics (CPO) module.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Photonic semiconductor devices, which are capable of transmitting or receiving signals via light, are becoming more and more common. Inter-device transmission via light has many advantages over electrical signals, particularly the avoidance of losses due to wire resistance and reduction of the impact of electromagnetic interference (EMI). However, the options for packaging photonic semiconductor devices have heretofore been limited and unsatisfactory in many ways. Therefore, a need exists for improved co-packaged optics (CPO) modules and methods of making them.

### BRIEF DESCRIPTION OF THE DRAWINGS

FIGS. 1a-1c illustrate a semiconductor wafer with a plurality of photonic semiconductor die separated by a saw street;

FIGS. 2a-2h illustrate forming a co-package optics (CPO) module;

FIGS. 3a and 3b illustrate an alternative process flow;

FIGS. 4a and 4b illustrate another alternative process flow;

FIGS. 5a and 5b illustrate an edge coupler used with the CPO module;

FIGS. 6a and 6b illustrate a grating coupler used with the CPO module; and

FIGS. 7a and 7b illustrate an electronic device with the CPO module.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

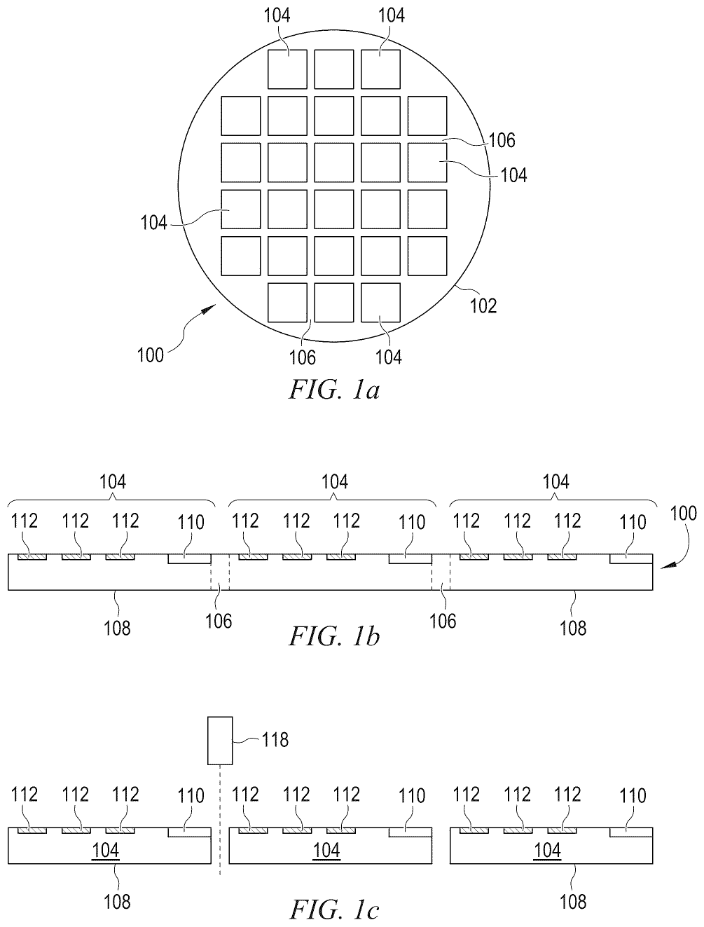

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of photonic semiconductor die is formed on wafer 100 separated by a non-active, inter-die wafer area or saw street 106. Saw street 106 provides cutting areas to singulate semiconductor wafer 100 into individual photonic semiconductor die 104. In one embodiment, semiconductor wafer 100 has a width or diameter of 100-450 millimeters (mm). Wafer 100 can include hundreds or thousands of photonic semiconductor die 104.

FIG. 1b shows a cross-sectional view of a portion of semiconductor wafer 100. Each photonic semiconductor die 104 has a back or non-active surface 108 and an active surface including a photonic circuit 110 formed within the die. The area of photonic circuit 110 may be referred to as a grating area because a grating connector is to be mounted there. The active surface may also include one or more transistors, diodes, and other circuit elements formed within the active surface to implement analog circuits or digital circuits, such as a digital signal processor (DSP), an application specific integrated circuit (ASIC), memory, or other signal processing circuit. Photonic semiconductor die 104 may also contain IPDs, such as inductors, capacitors, and resistors, for RF signal processing.

Wafer 100 is a wafer of photonic semiconductor die 104 as delivered by a manufacturer of the wafer to a manufacturer of semiconductor packages that will include the photonic semiconductor die. The manufacturer of wafer 100 has formed an interconnect structure over the active surface including contact pads 112 for external interconnect. The interconnect structure may have one or more layers of conductive traces with insulating layers formed between the layers. The interconnect structure also electrically interconnects photonic circuit 110 and contact pads 112 per the intended functionality of photonic semiconductor die 104.

The conductive layers, including contact pads 112, are formed over wafer 100 using physical vapor deposition (PVD), chemical vapor deposition (CVD), electrolytic plating, electroless plating, or another suitable metal deposition process. The conductive layers can be one or more layers of aluminum (Al), copper (Cu), tin (Sn), nickel (Ni), gold (Au), silver (Ag), or other suitable electrically conductive material. Any conductive layer mentioned above or below can be formed of the same methods and materials. Contact pads 112 include an under-bump metallization (UBM) in some embodiments.

In FIG. 1c, semiconductor wafer 100 is singulated through saw street 106 using a saw blade or laser cutting tool 118 into individual photonic semiconductor die 104. The individual photonic semiconductor die 104 can be inspected and electrically tested for identification of known good die (KGD) or known good unit (KGU) after singulation.

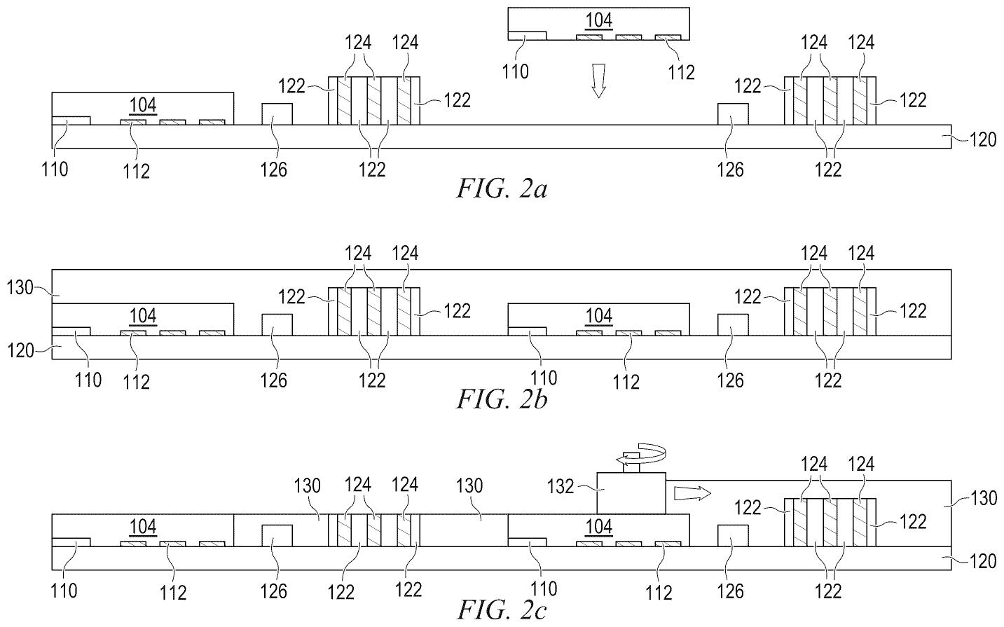

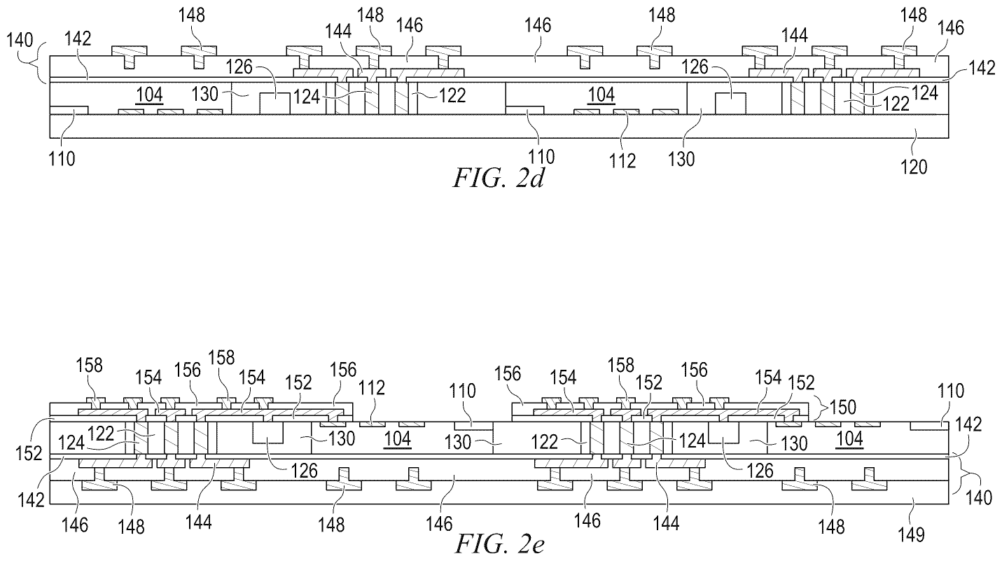

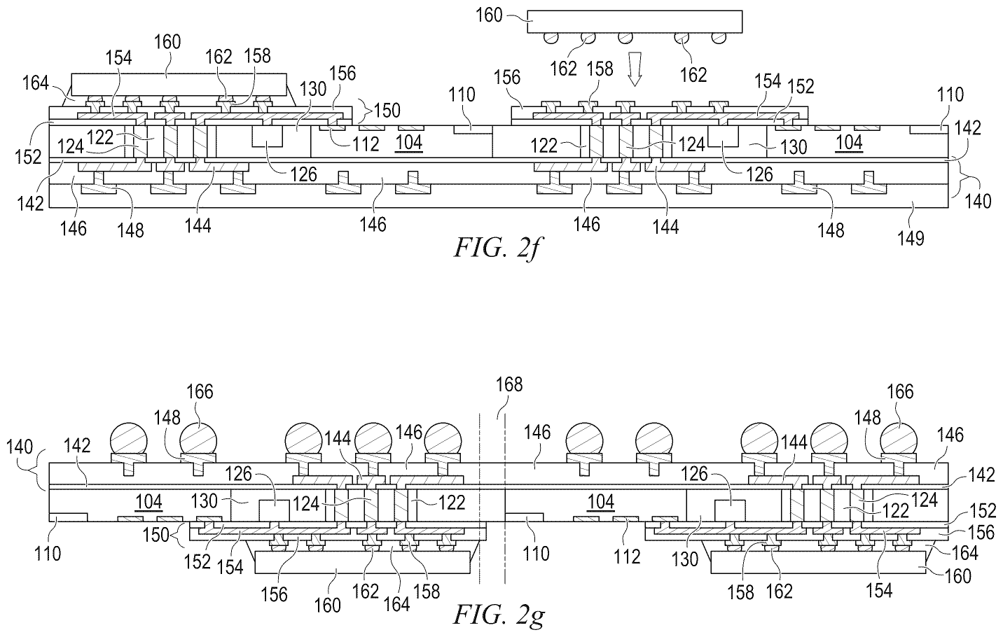

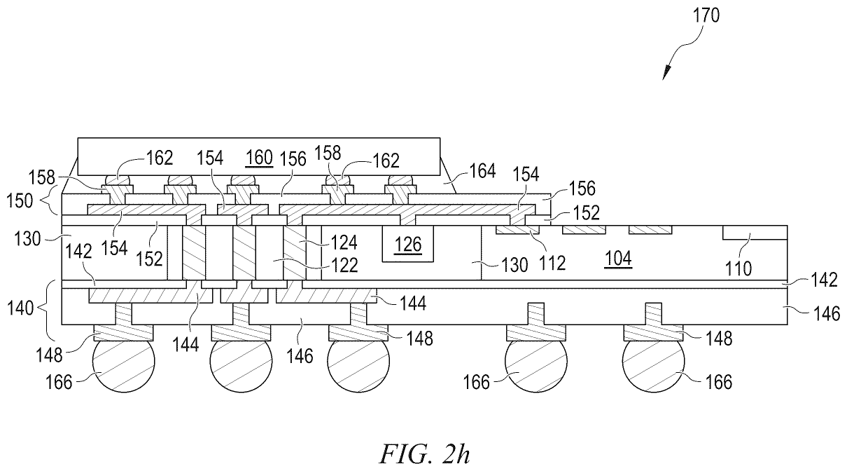

FIGS. 2a-2h illustrate the formation of a co-package optics (CPO) module including a photonic semiconductor die 104 packaged along with one or more other semiconductor die that provide the main functionality for the semiconductor package. A CPO module is a semiconductor package that is so-named because the main functional semiconductor die is co-packaged along with a photonic semiconductor die 104 to provide external communication via fiber optic cable or other optical communication mechanism.

In FIG. 2a, photonic semiconductor die 104 are picked and placed, or otherwise disposed, onto a carrier 120 with photonic circuit 110 oriented toward the carrier. Carrier 120 contains sacrificial base material such as silicon, polymer, beryllium oxide, glass, or other suitable low-cost, rigid material for structural support. An interface layer or double-sided tape is optionally formed or disposed over carrier 120 as a temporary adhesive bonding film, etch-stop layer, thermal release layer, or UV release layer. Two CPO modules are shown being formed on a single carrier 120 in the figures. Each CPO module includes a separate photonic semiconductor die 104. In other embodiments, many more than two units are formed at the same time using the steps shown below performed en masse.

A plurality of e-bars 122 is disposed on carrier 120 and will be embedded in the packages being formed. Embedded bars (e-bars) 122 can come with a wide variety of structural and functional features. The ‘e’ portion of the term e-bar means that the bar will be embedded within a substrate, encapsulated in an epoxy material or molding compound, or other similar device. The ‘bar’ portion of the term e-bar refers to the e-bar's shape being as a bar because e-bars are commonly, but optionally, elongated along a substantial majority of a length or width dimension of a substrate or semiconductor package, e.g., at least eighty percent. E-bars are also typically pre-formed prior to them being embedded, so the individual e-bars look like bars that are disposed onto carrier 120.

E-bars 122 include an insulating material base or core with conductive vias 124 formed through the insulating material. The base material for e-bars 122 can be any material described above or below for insulating layers, passivation layers, dielectric layers, or encapsulant. E-bars 122 are typically formed by depositing a layer of insulating material over a carrier, drilling or etching openings through the insulating material, and then filling the openings by sputtering conductive material to form conductive vias 124. Alternatively, conductive vias 124 can be formed first and then embedded in an encapsulant as described below for other encapsulants.

In other embodiments, e-bars have a flat metal base that conductive vias 124 extend from without any surrounding encapsulant or insulating material. An e-bar 122 may have no electrical function but can be just an insulating block used as filler in a substrate core, to balance warpage of the substrate, or for other purposes. An e-bar 122 may be a silicon bar with a deep trench capacitor (DTC). An e-bar 122 may be a glass bar with through-glass vias. An e-bar 122 may be a PCB/substrate bar with low coefficient of thermal expansion (CT) and high modulus. An e-bar 122 may include a magnetic core with an inductor formed by conductive vias around and conductive layers over the surfaces of the magnetic core.

Any combination of e-bars with any desired functionality can be disposed on carrier 120 along with e-bars 122 having conductive vias 124. Silicon capacitors (Si caps) 126 are disposed on carrier 120 as well. Si cap 126 are deep-trench capacitors formed in a silicon substrate in one embodiment. Any other type of discrete capacitor is used in other embodiments. Any number and type of electrical components can be disposed on carrier 120 along with photonic semiconductor die 104 to include their functionality in the package being formed, e.g., additional functional semiconductor die with or without vertical conductive vias through the die or a bridge die.

In FIG. 2b, encapsulant or molding compound 130 is deposited over and around carrier 120, e-bars 122, and Si caps 126 using a paste printing, compressive molding, transfer molding, liquid encapsulant molding, vacuum lamination, spin coating, or another suitable applicator. Encapsulant 130 can be liquid or granular polymer composite material, such as epoxy resin, epoxy acrylate, or polymer, with or without an added filler. In another embodiment, encapsulant 130 is a laminated mold sheet or film with or without fillers. Encapsulant 130 is non-conductive, provides structural support, and environmentally protects e-bars from external elements and contaminants. Encapsulant 130 can also be any of the materials and formed using any of the methods discussed below for insulating layers generally. Encapsulant 130 is a sheet of prepreg in one embodiment.

Photonic semiconductor die 104 are disposed face-down on carrier 120 when encapsulant 130 is deposited, which protects photonic circuit 110 and eliminates the need for an additional dam or sacrificial photoresist block to protect the photonic circuit 110. Photonic circuit 110 is pressed against carrier 120 so that encapsulant 130 does not flow onto the photonic circuit during molding. Encapsulant 130 completely covers the previously exposed surfaces of photonic semiconductor die 104, e-bars 122, and Si caps 126. In other embodiments, encapsulant 130 is deposited to have the tops of conductive vias 125 exposed from or coplanar to the top surface of the encapsulant, e.g., using film-assisted molding.

In FIG. 2c, encapsulant 130 is backgrinded using a grinder 132 to expose conductive vias 124 if not already exposed by the molding process. Chemical etching or another suitable process is used instead of grinder 132 in other embodiments. Portions of pillars 124 are removed by grinder 132 in some embodiments to ensure the pillars are exposed and coplanar to encapsulant 130. Optionally, back surfaces 108 of photonic semiconductor die 104 are exposed as well. Portions of photonic semiconductor die 104 can be removed by grinder 132 to reduce a thickness of the photonic semiconductor die.

In FIG. 2d, a build-up interconnect structure 140 is formed over encapsulant 130. Interconnect structure 140 being called a build-up interconnect structure refers to the way that the interconnect structure is formed by successively building up insulating layers and conductive layers over encapsulant 130 until the desired signal routing is achieved.

Forming interconnect structure 140 starts by forming an insulating or passivation layer 142 on encapsulant 130, back surface 108 of photonic semiconductor die 104, and e-bars 122. Insulating layer 140 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Insulating layer 142 can be formed using PVD, CVD, printing, lamination, spin coating, spray coating, sintering, or thermal oxidation. Any insulating, passivation, or dielectric layer mentioned above or below can be formed using any of the materials or methods described for insulating layer 142.

Openings are formed through insulating layer 142 using chemical etching, photolithography, mechanical drilling, laser drilling, or another suitable process to expose conductive vias 124. A conductive layer 144 is formed over insulating layer 142 and includes conductive vias extending through the openings to physically and electrically contact conductive vias 124. Conductive layer 144 includes conductive traces to fan-out from conductive vias 124 and, optionally, contact pads at both ends of the traces for connecting to the underlying conductive vias and for subsequent formation of overlying conductive structures. Conductive layer 144 is formed using any of the methods and materials described above for conductive layer 112. Any suitable conductive layer deposition and patterning method can be used in other embodiments, e.g., using an additive or subtractive process. Any conductive layer mentioned above or below can be formed as described for conductive layers 144 and 112. In some embodiments, conductive layer 144 is formed first on encapsulant 130 without passivation layer 142.

An insulating layer 146 is formed over passivation layer 142 and conductive layer 144 as described above for passivation layer 142. Openings are formed through insulating layer 146 to expose contact pads of the underlying conductive layer 144. The openings can be formed by chemical etching, photolithography, mechanical drilling, laser drilling, or any other suitable means. Additional conductive layers and insulating layers can be interleaved over encapsulant 130 as needed to implement the desired electrical signal routing.

After the desired number of conductive layers and insulating layers have been built up, contact pads or under-bump metallization (UBM) pads 148 are formed on the top conductive layer 144 through openings in the top insulating layer 146. UBM pads 148 include conductive vias or otherwise extend through insulating layer 146 to physically and electrically contact the underlying conductive layer 144. In some embodiments, UBM pads 148 are formed of multiple conductive layers including a wetting layer, barrier layer, and adhesion layer. UBM pads 148 can have a flat top surface as illustrated or be formed conformally in the openings of the top insulating layer 146. A passivation or solder resist layer is optionally formed over UBM pads 148.

In FIG. 2e, carrier 120 is removed from encapsulant 130 using thermal, laser, UV, or other energy to reduce adhesion of the release layer. The panel of encapsulant 130, photonic semiconductor die 104, e-bars 122, and interconnect structure 140 is flipped so that photonic circuits 110 are exposed. The panel is optionally disposed back on carrier 120 or another similar carrier. Backgrinding tape 149 is used in one embodiment.

An interconnect structure 150 is formed over photonic semiconductor die 104 and encapsulant 130. Interconnect structure 150 optionally includes openings over photonic circuit 110 to allow a subsequent optical connection. Interconnect structure 150 is a build-up interconnect structure formed in a similar manner to interconnect structure 140.

Insulating layer 152 is formed on encapsulant 130, e-bars 122, Si caps 126, and photonic die 104 as described above for insulating layer 142. Openings are formed through insulating layer 152 to expose conductive vias 124. In one embodiment, openings to expose photonic circuit 110 are formed through insulating layer 152 immediately after the insulating layer is formed and before forming conductive layer 154 on the insulating layer. The openings over photonic circuit 110 can be formed at the same time and using the same process as the openings over conductive vias 124. In other embodiments, the openings over photonic circuit 110 are formed through all layers of interconnect structure 150 together after interconnect structure 150 is completed.

A conductive layer 154 is formed over insulating layer 152 as described above for conductive layer 144. Conductive layer 154 has conductive vias that extend through the openings of insulating layer 152 to physically and electrically contact conductive vias 124, contact pads 112 of photonic semiconductor die 104, and contact pads of Si capacitors 126. Conductive layer 154 is electrically connected to conductive layer 144 by conductive vias 124. Insulating layer 156 is formed over conductive layer 154 as described above for insulating layer 146. Openings are formed through insulating layer 156 over photonic circuit 110 as described above for insulating layer 152, either immediately or after completing interconnect structure 150. UBM 158 are formed through openings of insulating layer 156 on conductive layer 154 as described above for UBM 148.

In FIG. 2f, semiconductor die 160 are picked and placed, or otherwise disposed, on interconnect structure 150. Semiconductor die 160 are similar to photonic semiconductor die 104 but have no photonic circuit 110. Instead, semiconductor die 160 have active circuits implementing the main functionality of the packages being formed, e.g., a microprocessor, graphics processing unit, or other functional unit. In other embodiments, a chiplet, system-in-package, or other type of subpackage is mounted instead of, or in addition to, a bare semiconductor die 160. More than one semiconductor die or subpackage is used in each CPO module in some embodiments.

Semiconductor die 160 includes solder bumps 162 formed on the semiconductor die. Solder bumps 162 are formed on contact pads or UBM of semiconductor die 160. An electrically conductive bump material is deposited over the contact pads using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to the contact pads using a suitable attachment or bonding process. In one embodiment, the bump material is reflowed by heating the material above its melting point to form balls or bumps 162. Solder bump 162 can also be compression bonded or thermocompression bonded to the contact pads. Solder bump 162 represents one type of interconnect structure that can be formed over semiconductor die 160. The interconnect structure can also use bond wires, conductive paste, stud bump, micro bump, or other electrical interconnect. An underfill 164 is optionally dispensed between interconnect structure 150 and semiconductor die 160.

In FIG. 2g, the panel from FIG. 2f is flipped and backgrinding tape 149 is removed to expose UBM pads 148 for processing. Solder bumps 166 are formed on UBM pads 148 as described above for solder bumps 162. Solder bumps 166 are electrically coupled to semiconductor die 160, Si cap 126, and photonic semiconductor die 104 by interconnect structure 140, conductive vias 124, and interconnect structure 150. In some embodiments, copper pillars are formed on UBM pads 148 instead of solder bumps. The copper pillars have optional solder caps.

The panel in FIG. 2g is singulated between units at saw street 168 using a saw blade, laser cutting tool, or other appropriate mechanism to separate a plurality of co-packaged optics (CPO) modules 170 as shown in FIG. 2h. CPO module 170 integrates a photonic semiconductor die 104 into a package with a functional semiconductor die 160 using an improved process flow that protects photonic circuit 110 with a reduced number of steps.

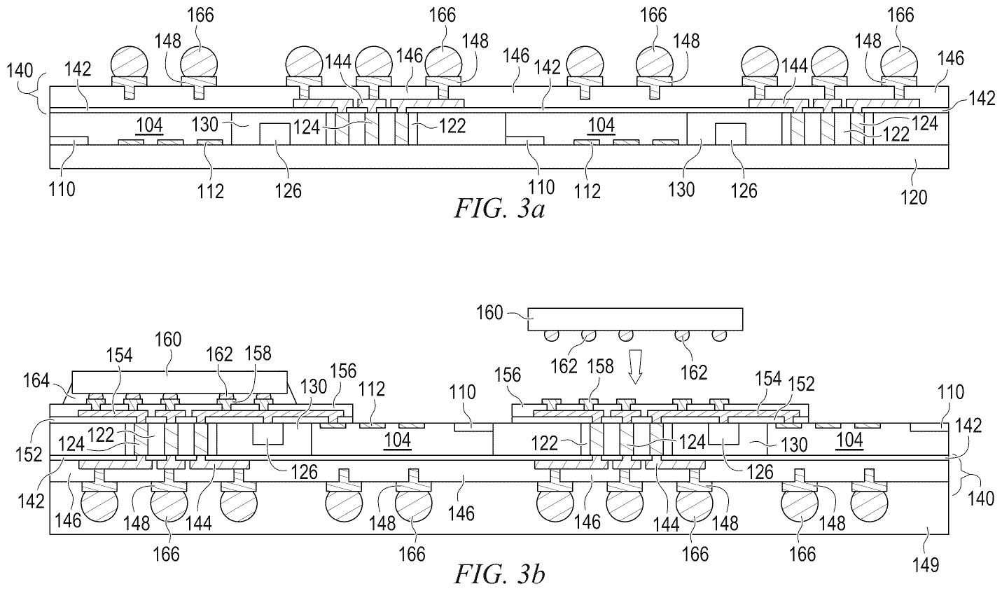

FIGS. 3a and 3b illustrate an alternative process flow for forming CPO module 170. In FIG. 3a, solder bumps 166 are formed on interconnect structure 140 while the panel remains on carrier 120, immediately after forming interconnect structure 140 in FIG. 2d and before flipping to form interconnect structure 150 in FIG. 2e. Further processing proceeds as shown in FIGS. 2e and 2f, but with bumps 166 already formed as shown in FIG. 3b. The units are then singulated to separate CPO modules 170 as shown in FIGS. 2g and 2h.

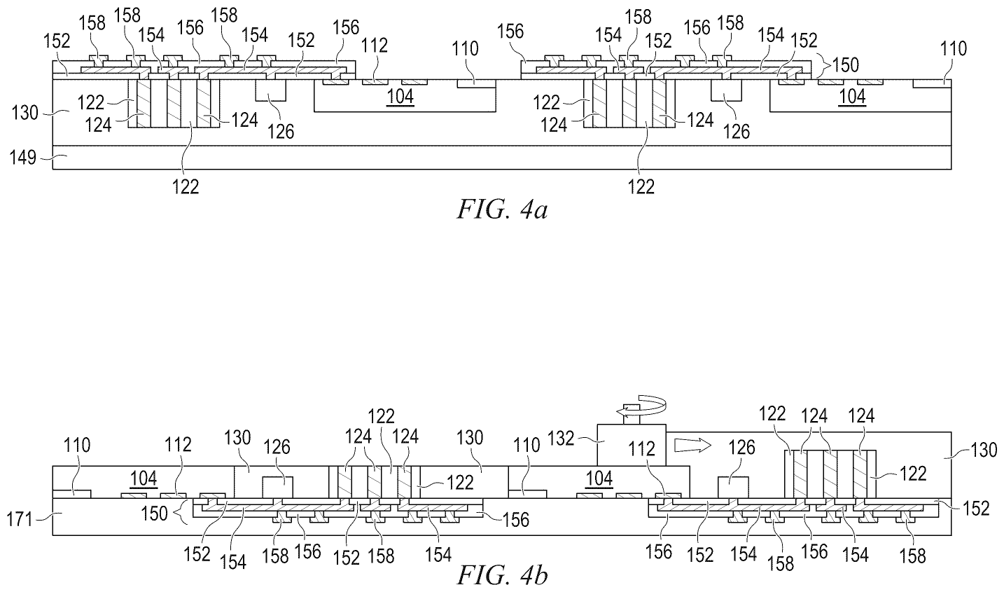

FIGS. 4a and 4b illustrate another alternative process flow. After depositing encapsulant 130 in FIG. 2b, the panel is debonded from the carrier, flipped, and interconnect structures 150 are formed prior to backgrinding in FIG. 2c. After forming interconnect structures 150 in FIG. 4a, the panel is flipped onto backgrinding tape 171 and backgrinded as shown in FIG. 4b.

Interconnect structure 140 and bumps 166 are formed as shown in FIGS. 2d and 2g before singulating CPO modules 170 from each other.

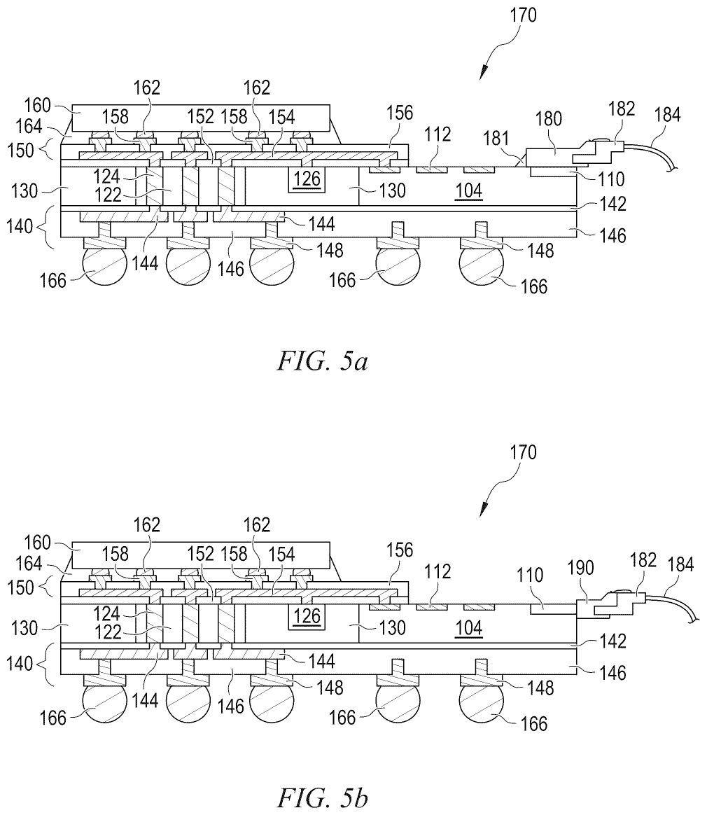

FIGS. 5a and 5b illustrate attaching a fiber optic cable to CPO modules 170 using an edge coupler. FIG. 5a shows a connector 180 attached to the top surface of photonic semiconductor die 104 over photonic circuit 110. An optical adhesive 181 is used to attach the connector 180. A thin layer of adhesive 181, not illustrated, exists between connector 180 and photonic semiconductor die 104. A fiber array unit (FAU) 182 has one or more fiber optic cables 184 attached and extending from the FAU. FAU 182 is inserted and clipped into connector 180. Connector 180 or FAU 182 guides the light from fiber optic cables 184 to photonic circuit 110. In other embodiments, fiber optic cables 184 are attached directly to photonic circuit 110 with optional v-shaped trenches for the cables to set in.

FIG. 5b shows connector 190 attached to a side surface of photonic semiconductor die 104 directly adjacent to photonic circuit 110. Connector 190 is attached to photonic semiconductor die 104 using a layer of adhesive 181. FAU 182 is inserted and clipped into connector 190. Photonic semiconductor die 104 is able to send and receive signals to and from functional semiconductor die 160 optically over fiber optic cables 182.

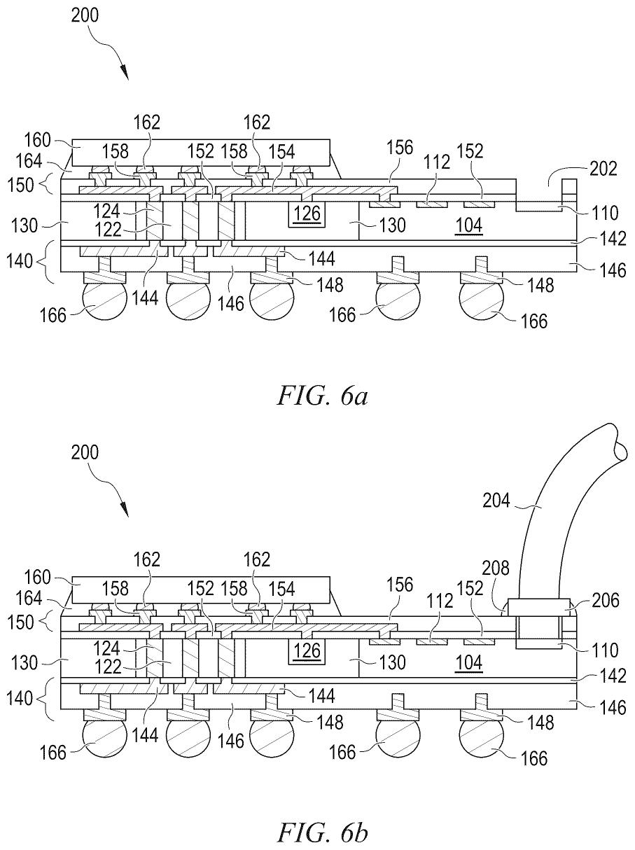

FIGS. 6a and 6b illustrate a CPO module 200 that has a grating coupler used instead of an edge coupler. Insulating layers 152 and 156 extend to and completely surround photonic circuit 110 in FIG. 6a. An opening 202 formed through insulating layers 152 and 156 is aligned to and approximately the same size as photonic circuit 110. Opening 202 can be a trench formed through interconnect structure 150 after completion.

In FIG. 6b, a fiber optic cable 204 has a ferrule 206 attached to the fiber optic cable with adhesive. Ferrule 206 acts as a flange to allow fiber optic cable 204 to be attached to insulating layer 156 with an adhesive 208. Adhesive 208 extends as a layer between ferrule 206 and insulating layer 156 to attach fiber optic cable 204 to CPO module 200. Any number of fiber optic cables can be separately attached to separate openings 202. In some embodiments, a FAU is used to attach multiple fiber optic cables at once to a single opening 202. CPO module 200 is formed substantially as shown above in FIGS. 2a-2h and can also use the alternative process flows shown in FIGS. 3a, 3b, 4a, and 4b.

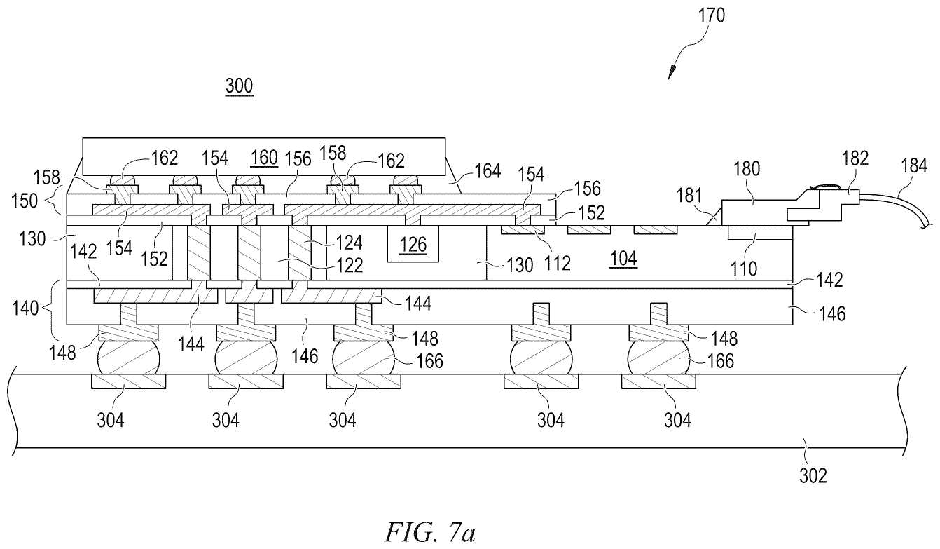

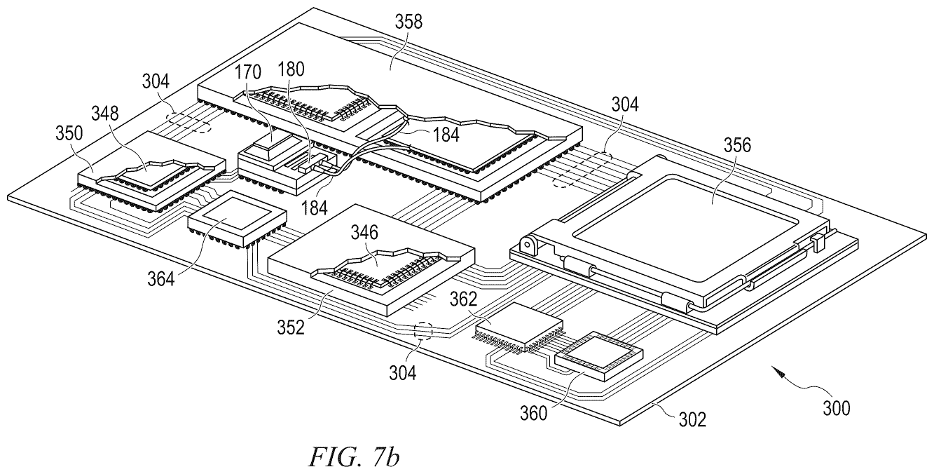

FIGS. 7a and 7b illustrate integrating the above-described semiconductor packages, e.g., CPO module 170, into a larger electronic device 300. FIG. 7a illustrates a partial cross-section of CPO module 170 mounted onto a printed circuit board (PCB) or other substrate 302 as part of electronic device 300. Solder bumps 166 are reflowed onto conductive layer 304 of PCB 302 to physically attach and electrically connect CPO module 170 to the PCB. In other embodiments, thermocompression or another suitable attachment and connection methods are used. In some embodiments, an adhesive or underfill layer is used between CPO module 170 and PCB 302. Semiconductor die 160 is electrically coupled to conductive layer 304 through substrate interconnect structure 150, conductive vias 124, and interconnect structure 140.

FIG. 7b illustrates electronic device 300 having a chip carrier substrate or PCB 302 with a plurality of semiconductor packages disposed on a surface of PCB 302, including CPO module 170. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 7b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, which lowers costs up and down the supply chain.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a photonic semiconductor die;
disposing the photonic semiconductor die on a carrier with a photonic circuit of the photonic semiconductor die oriented toward the carrier;
disposing an e-bar on the carrier;
depositing an encapsulant over the photonic semiconductor die and e-bar;
backgrinding a first surface of the encapsulant to expose the e-bar;
forming a first build-up interconnect structure over the first surface of the encapsulant; and
forming a second build-up interconnect structure over a second surface of the encapsulant, wherein the photonic circuit is exposed through an opening of the second build-up interconnect structure.

2. The method of claim 1, further including disposing a silicon capacitor on the carrier.

3. The method of claim 1, wherein the e-bar includes a core and a conductive via extending through the core.

4. The method of claim 1, further including disposing a semiconductor die over the second build-up interconnect structure.

5. The method of claim 4, wherein the second build-up interconnect structure electrically connects the semiconductor die to the photonic semiconductor die.

6. The method of claim 1, further including mounting a fiber array unit to the photonic circuit.

7. A method of making a semiconductor device, comprising:
providing a photonic semiconductor die;
disposing the photonic semiconductor die on a carrier with a photonic circuit of the photonic semiconductor die oriented toward the carrier;
depositing an encapsulant over the photonic semiconductor die;
forming a first build-up interconnect structure over a first surface of the encapsulant; and
forming a second build-up interconnect structure over a second surface of the encapsulant, wherein the photonic circuit is exposed through an opening of the second build-up interconnect structure.

8. The method of claim 7, further including disposing an e-bar on the carrier.

9. The method of claim 8, wherein the e-bar includes a core and a conductive via extending through the core.

10. The method of claim 8, further including disposing a silicon capacitor on the carrier.

11. The method of claim 7, further including disposing a semiconductor die over the second build-up interconnect structure.

12. The method of claim 11, wherein the second build-up interconnect structure electrically connects the semiconductor die to the photonic semiconductor die.

13. The method of claim 7, further including mounting a fiber array unit over the photonic circuit.

14. A semiconductor device, comprising:
a photonic semiconductor die;
an e-bar disposed adjacent to the photonic semiconductor die;
an encapsulant deposited over the photonic semiconductor die and e-bar;
a first build-up interconnect structure formed over a first surface of the encapsulant; and
a second build-up interconnect structure formed over a second surface of the encapsulant, wherein the photonic circuit is exposed through an opening of the second build-up interconnect structure.

15. The semiconductor device of claim 14, further including a silicon capacitor in the encapsulant.

16. The semiconductor device of claim 14, wherein the e-bar includes a core and a conductive via extending through the core.

17. The semiconductor device of claim 14, further including a semiconductor die disposed over the second build-up interconnect structure.

18. The semiconductor device of claim 17, wherein the second build-up interconnect structure electrically connects the semiconductor die to the photonic semiconductor die.

19. The semiconductor device of claim 14, further including a fiber array unit mounted over the photonic circuit.

20. A semiconductor device, comprising:
a photonic semiconductor die;
an encapsulant deposited over the photonic semiconductor die;
a first build-up interconnect structure formed over a first surface of the encapsulant; and
a second build-up interconnect structure formed over a second surface of the encapsulant, wherein the photonic circuit is exposed through an opening of the second build-up interconnect structure.

21. The semiconductor device of claim 20, further including an e-bar disposed in the encapsulant.

22. The semiconductor device of claim 21, wherein the e-bar includes a core and a conductive via extending through the core.

23. The semiconductor device of claim 21, further including a silicon capacitor disposed in the encapsulant.

24. The semiconductor device of claim 20, further including a semiconductor die disposed over the second build-up interconnect structure.

25. The semiconductor device of claim 20, further including a fiber array unit mounted over the photonic circuit.
